(19) United States
(12) Patent Application Publication
(10) Pub. No.: US 2025/0383601 A1
(43) Pub. Date: Dec. 18, 2025

(54) ENHANCED EUV PHOTORESISTS AND METHODS OF THEIR USE

(71) Applicants: Alex Phillip Graham Robinson, Birmingham (GB); Alexandra McClelland, Worcester (GB); Fernanda Meloni, Worcester (GB); Van Huy Nguyen, Worcester (GB); Gregory O'Callaghan, Hagley (GB); Edward Jackson, Franklin, MA (US); John Roth, Cohasset, MA (US); Tim McCoy, Westwood, MA (US); Tom Lada, Somerville, MA (US)

(72) Inventors: Alex Phillip Graham Robinson, Birmingham (GB); Alexandra McClelland, Worcester (GB); Fernanda Meloni, Worcester (GB); Van Huy Nguyen, Worcester (GB); Gregory O'Callaghan, Hagley (GB); Edward Jackson, Franklin, MA (US); John Roth, Cohasset, MA (US); Tim McCoy, Westwood, MA (US); Tom Lada, Somerville, MA (US)

(73) Assignee: Irresistible Materials LTD, Birmingham, GB (GB)

(21) Appl. No.: 18/867,334

(22) PCT Filed: May 22, 2023
(86) PCT No.: PCT/US2023/023083

§ 371 Date: Nov. 19, 2024

Related U.S. Application Data
(60) Provisional application No. 63/344,604, filed on May 22, 2022.

(51) Int. Cl. G03F 7/028; G03F 7/004

(52) U.S. Cl. CPC G03F 7/028; G03F 7/0046

(57) ABSTRACT

The current application discloses zwitterion materials useful in EUV photolithographic resist compositions. The compositions provide improvements in photodefined line geometires as well as increased lithographic photospeed. Also provided are resist compositions containing the disclosed novel zwitterions.

### FIELD OF INVENTION

The present application for patent discloses novel zwitterionic materials with improved sensitivity (photospeed), resolution (line width roughness) or both when formulated in EUV photoresists.

### BACKGROUND

Extreme ultraviolet lithography (EUVL) is one of the leading technology options to replace optical lithography for volume semiconductor manufacturing at feature sizes <20 nm. The extremely short wavelength (13.4 nm) is a key enabling factor for high resolution required at multiple technology generations. In addition, the overall system concept—scanning exposure, projection optics, mask format, and resist technology—is quite similar to that used for current optical technologies. Like previous lithography generations, EUVL consists of resist technology, exposure tool technology, and mask technology. The key challenges are EUV source power and throughput. Any improvement in EUV power source will directly impact the currently strict resist sensitivity specification. Indeed, a major issue in EUVL imaging is resist sensitivity, the lower the sensitivity, the greater the source power that is needed or the longer the exposure time that is required to fully expose the resist. The lower the power levels, the more noise affects the line edge roughness (LER) of the printed lines.

Various attempts have been made to alter the make-up of EUV photoresist compositions to improve performance of functional properties. Electronic device manufacturers continually seek increased resolution of a patterned photoresist image. It would be desirable to have new photoresist compositions that could provide enhanced imaging capabilities, including new photoresist compositions useful for EUVL.

As is well known, the manufacturing process of various kinds of electronic or semiconductor devices such as ICs, LSIs and the like involves fine patterning of a resist layer on the surface of a substrate material such as, for example, a semiconductor silicon wafer. This fine patterning process has traditionally been conducted by the photolithographic method in which the substrate surface is uniformly coated with a positive or negative tone photosensitive composition to form a thin layer and selectively irradiating with actinic rays (such as ultraviolet (UV), deep UV, vacuum UV, extreme UV, x-rays, electron beams and ion beams) via a transmission or reflecting mask followed by a development treatment to selectively dissolve away the coated photosensitive layer in the areas exposed or unexposed, respectively, to the actinic rays leaving a patterned resist layer on the substrate surface. The patterned resist layer, thus obtained, may be utilized as a mask in the subsequent treatment on the substrate surface such as etching. The fabrication of structure with dimensions of the order of nanometers is an area of considerable interest since it enables the realization of electronic and optical devices which exploit novel phenomena such as quantum confinement effects and also allows greater component packing density. As a result, the resist pattern is required to have an ever-increasing fineness which can be accomplished by using actinic rays having a shorter wavelength than the conventional ultraviolet light. Accordingly, it is now the case that, in place of the conventional ultraviolet light, electron beams (e-beams), excimer laser beams, EUV, BEUV and X-rays are used as the short wavelength actinic rays. The minimum size obtainable is, in part, determined by the performance of the resist material and, in part, the wavelength of the actinic rays. Various materials have been proposed as suitable resist materials. For example, in the case of negative tone resists based on polymer crosslinking, there is an inherent resolution limit of about IO nm, which is the approximate radius of a single polymer molecule.

It is also known to apply a technique called “chemical amplification” to resist materials. A chemically amplified resist material is generally a multi-component formulation in which there is a matrix material, frequently a main polymeric component, such as a polyhydroxystyrene (PROST) resin protected by acid labile groups and a photo acid generator (PAG), as well as one or more additional components which impart desired properties to the resist. The matrix material contributes toward properties such as etching resistance and mechanical stability. The chemical amplification occurs through a catalytic process involving the PAG, which results in a single irradiation event causing the transformation of multiple resist molecules. The acid produced by the PAG reacts catalytically with the polymer to cause it to lose a functional group or, alternatively, cause a crosslinking event. The speed of the reaction can be driven, for example, by heating the resist film. In this way the apparent sensitivity of the material to actinic radiation is greatly increased, as small numbers of irradiation events give rise to a large number of solubility changing events. As noted above, chemically amplified resists may be either positive or negative working.

As the requirement for feature size continues to be reduced, below 20 nm for example, there is a need to control the cationic polymerization and/or crosslinking, in negative working systems. Photoresists based on acid catalyzed deprotection such as in positive working systems, typically utilize base quenchers which control the migration of the many photogenerated acids to areas where deprotection is not desired. Epoxy-based negative working photoresist are initiated by photogenerated acid, but the active polymerization and crosslinking species is not a photoacid. (See FIG. 1). It can readily be seen that after initial reaction of the epoxy, or other group, such as, for example, an oxetane, or an acid-labile protecting group, the continuation involves the photoacid protonation of the epoxy (or oxetane) oxygen to provide an epoxonium intermediate. However, after this initiating stage, the reaction continues by attack of the epoxonium intermediate by the oxygen of a neutral epoxy group. Propagation, polymerization and/or crosslinking then continues until termination. In these photopattern processes controlling the polymerization and/or crosslinking becomes important to prevent line growth, sharpening or line width reduction and polymer growth in areas which are undesirable. These problems include line edge roughness, line width reduction, line wiggle and other less than desirable pattern geometries. This concept is critical in line and space geometries less than 20 nm. Thus, any methods that will control the polymerization and/or crosslinking in photosystems, such as for example, EUV, is highly desirable.

Stable anions useful in the current disclosure include, for example, zwitterions which contain a stable carbanion associated with a positive charge elsewhere on the molecule, see, for example, FIG. 2.

Disclosed and claimed herein are photolithographic compositions containing at least one zwitterion as described above.

As used herein the term acid, proton and H+ are used interchangeably and refer to the acidic ion of a protic acid.

As mentioned, base quenchers have been used in standard positive working systems where initiation and propagation are reliant on the photogenerated acid. In the negative systems of the current disclosure photogenerated acid function to initiate the curing process, while further polymerization and/or crosslinking does not depend on the acid. Base quenchers used for typical photolithographic systems only have a very limited effect in the currently presented systems which are required to generate line and space geometries below 20 nm.

The stable anions of the current disclosure are incorporated into photoresists which contain photoacid generating components. Depending on the energy source, such as, for example, I-line (365 nm wavelength) or Extreme UV (EUV, 13 nm), the amount of acid generated per photo exposure will vary. EUV will generate more acid than lower energy exposure, such as I-line.

Not to be held to theory it is believed that the stable anion acts as an acid buffer in regions of high light/radiation intensity. The term buffering as used herein refers to the interaction of the stable anion additive with a photogenerated acid.

In exposures based on Extreme UV, where many H+ atoms are generated (via photoelectron generation) such buffering appears to improve the structure, definition and integrity of photolithographically created patterns.

In regions of high exposure, it is believed that the stable anions of the photoresist react with the high levels of photogenerated acid. The remaining acid then reacts with the polymerization and/or crosslinking components of the resist. In this example, the epoxy polymerization and/or crosslinking components of the resist are the epoxy components.

In regions of low exposure or where there is acid migration, where low levels of photogenerated acid occurs, the stable anion acts as a quencher, stopping the initiation and/or propagation of polymerization and/or crosslinking, from moving into unexposed regions preventing undesirable photopattern structures, FIG. 3. In addition, the stable anions act as acid scavengers in these low light systems.

Research has shown that the stable anions of photoresist, especially in EUV resists, of the current disclosure, increase contrast and reduce LER due to their buffering and quenching properties. Further we believe that the stable anions of the current disclosure act as a quencher which stops polymerization of the photosensitive composition from migrating into unexposed areas.

In high light intensity regions, the stable anion that has already been used as a buffer can no longer act as a quencher. Where the stable anion has already been used as a buffer, propagation or chain transfers (the mechanisms of polymerization) will proceed as is desired. The stable anion may be acting as a very effective molecular switch.

Examples of synthesis of dipole compounds useful for the current disclosure can be found in U.S. Pat. Nos. 9,122,156, 9,229,322, and 9,519,215, all to Robinson, et al and in corporate herein by reference.

### DESCRIPTION OF FIGURES

FIG. 1 shows the mechanism for polymerization and propagation of epoxy material polymerization.

FIG. 2 shows the zwitterion functionality of the currently disclosed materials.

FIG. 3 shows a theoretical route by which the zwitterions of the current disclosure.

FIGS. 4-7 show examples of the novel zwitterions disclosed and claimed in the current disclosure.

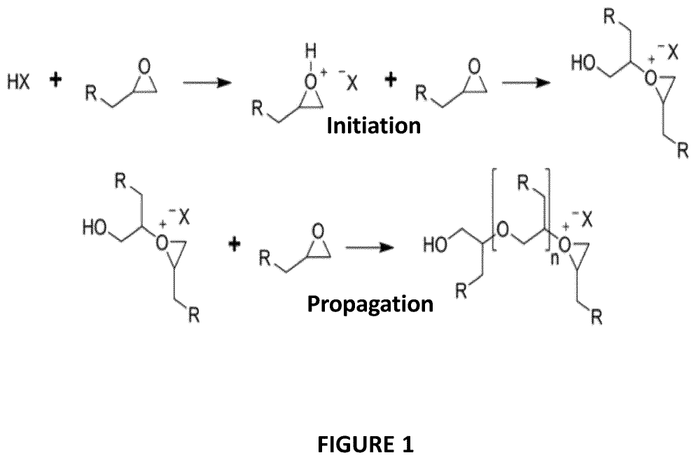

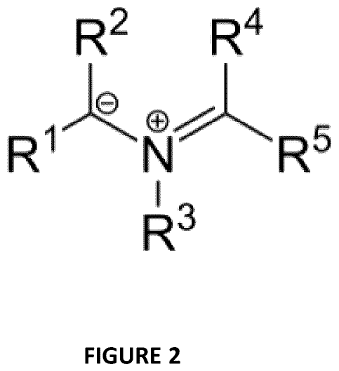

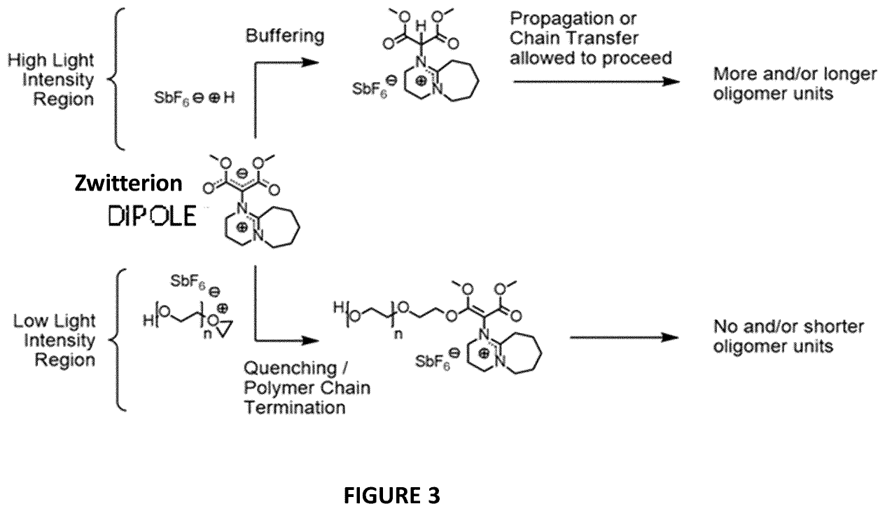

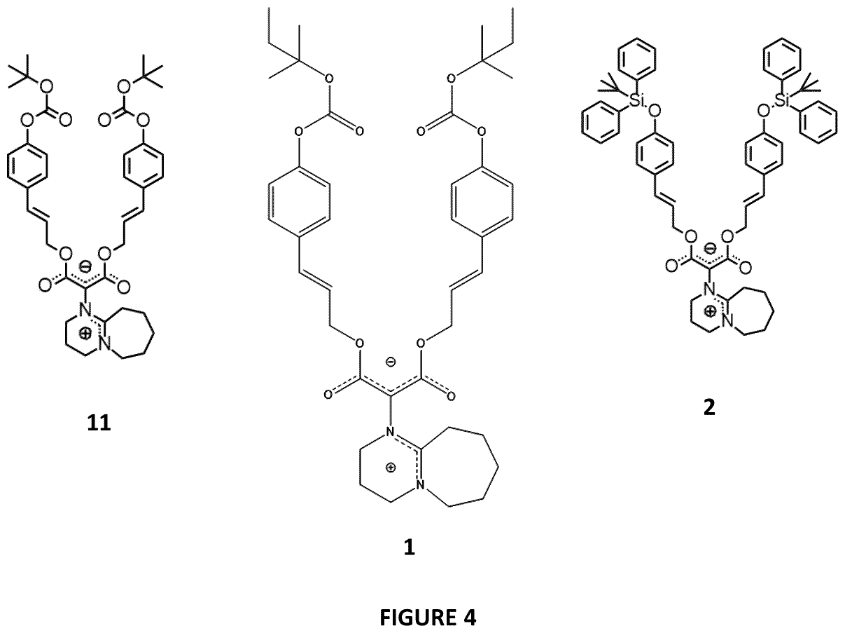

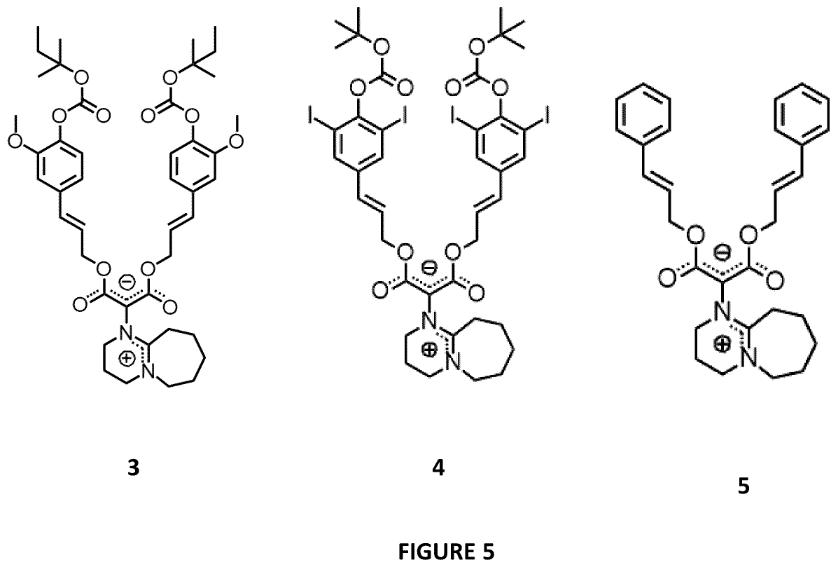

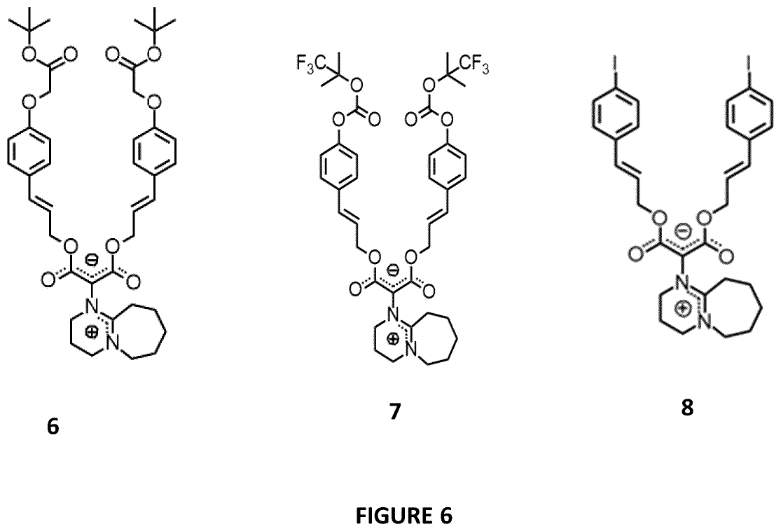

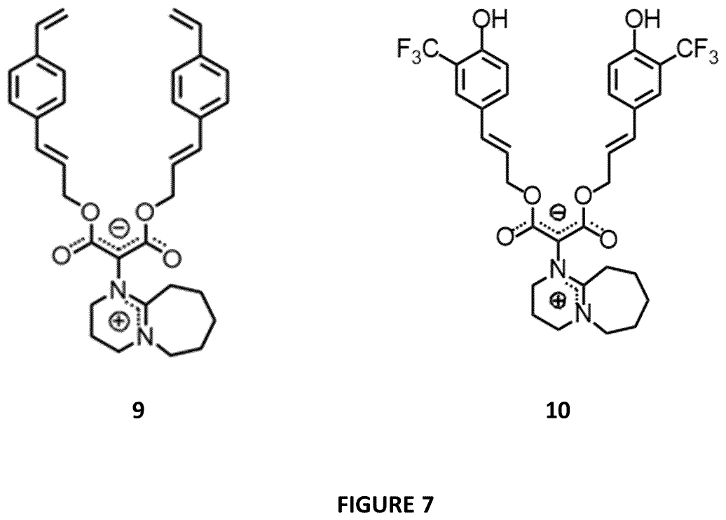

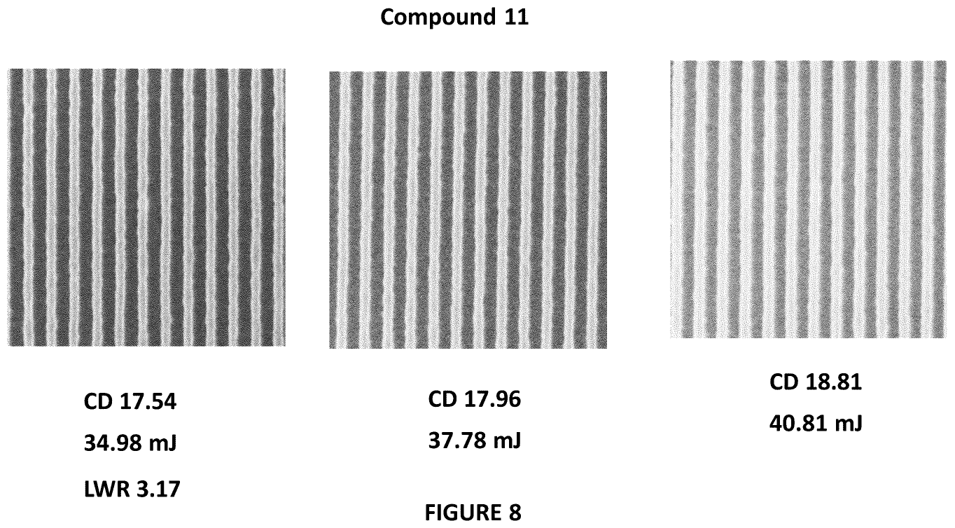

### DETAILED DESCRIPTION OF THE DISCLOSURE

As used herein, the conjunction “and” is intended to be inclusive and the conjunction “or” is not intended to be exclusive unless otherwise indicated or required by the context. For example, the phrase “or, alternatively” is intended to be exclusive. As used herein, the term “exemplary” is intended to describe an example and is not intended to indicate preference. As used herein, the term “energetically accessible” is used to describe products that may be thermodynamically or kinetically available via a chemical reaction.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

We have surprisingly found that the addition of certain, stable dipole materials to either positive or negative resists, improve the geometries and integrity of lines and spaces after EUV exposure and processing, such as, for example, improvements in line edge roughness, line wiggle, undercutting, bridging, line collapse, and the like.

As used herein, the term “dipole” means a molecule which contains both a positive charge center and a negative charge center on the same molecule, either alpha to each other or spaced further in the molecule. Further as used herein, the term “dipole” refers to zwitterions and is not meant to mean any one particular molecule but a representative molecule of the group.

Zwitterion, also called an inner salt, compounds are neutral compounds having formal unit electrical charges of opposite sign.

In a first embodiment, disclosed and claimed herein are compositions of matter comprising the chemical structure:

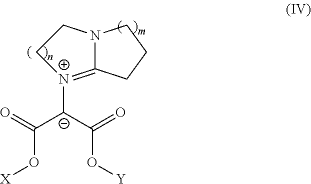

wherein m=1-4, n=1-4, and wherein X and Y are the same or different and are branched or unbranched, substituted or unsubstituted chains of 1-24 carbon atoms comprising alkyl groups, alkenyl groups, aromatic groups, oxygen groups, substituted aromatic groups or combinations thereof.

In a second embodiment, disclosed and claimed herein are compositions of matter of the above embodiment wherein m=2 and n=3 and the chains have O-16 heteroatoms substituted onto the chains and comprise substituted or unsubstituted aryl groups, heteroaromatic groups, or fused aromatic or fused heteroaromatic groups or combinations of both and wherein the aromatic groups comprise one or more substituents comprising t-butoxycarbonyloxy groups, t-butyl ester groups, t-butyl ester ether groups, t-pentoxycarbonyloxy groups, hydroxy groups, ether groups, alkyl or alkenyl substituents, alkylsilyl groups, siloxy groups comprising aromatic substituents, or a combination thereof.

In a third embodiment, disclosed and claimed herein are compositions of matter of the above embodiments further comprising, in admixture, one or more photoacid generators chosen from a sulfonium salt, an iodonium salt, a sulfone imide, a halogen-containing compound, a sulfone compound, an ester sulfonate compound, a diazomethane compound, a dicarboximidyl sulfonic acid ester, an ylideneaminooxy sulfonic acid ester, a sulfanyldiazomethane, or a mixture thereof.

In a fourth embodiment, disclosed and claimed herein are compositions of matter of the above embodiments further comprising, at least one crosslinker, wherein the at least one crosslinker comprises an acid sensitive monomer, oligomer or polymer, and wherein the at least one crosslinker comprises at least one of an epoxy group, an oxetane group, an oxabicyclo[4.1.0]heptane-ether group, a oxetanemethanol group, a glycidyl ether, a glycidyl ether of an aromatic group, glycidyl ester, glycidyl amine, a methoxymethyl group, an ethoxy methyl group, a butoxymethyl group, a benzyloxymethyl group, dimethylamino methyl group, diethylamino methyl group, a dibutoxymethyl group, a dimethylol amino methyl group, diethylol amino methyl group, a dibutylol amino methyl group, a morpholino methyl group, acetoxymethyl group, benzyloxy methyl group, formyl group, acetyl group, vinyl group or an isopropenyl group.

In a fifth embodiment, disclosed and claimed herein are compositions of matter of the above embodiments further comprising a solvent comprising ethers, esters, etheresters, ketones and ketoneesters and, more specifically, ethylene glycol monoalkyl ethers, diethylene glycol dialkyl ethers, propylene glycol monoalkyl ethers, propylene glycol dialkyl ethers, alkyl phenyl ethers such as anisole, acetate esters, hydroxyacetate esters, and lactate esters, such as ethyl lactate. The aforementioned solvents may be used independently or as a mixture of two or more types. Furthermore, at least one type of high boiling point solvent such as benzylethyl ether, dihexyl ether, diethylene glycol monomethyl ether, diethylene glycol monoethyl ether, acetonylacetone, isoholon, caproic acid, capric acid, 1-octanol, 1-nonanol, benzyl alcohol, benzyl acetate, ethyl benzoate, diethyl oxalate, diethyl maleate, y-butyrolactone, ethylene carbonate, propylene carbonate and phenylcellosolve acetate may be added to the aforementioned solvent. Other suitable solvents include halogenated solvents.

In a sixth embodiment, disclosed and claimed herein are compositions of matter of the above embodiments further wherein the chains and/or the groups on the chains are substituted with one of more iodides, fluorides, and/or fluorocarbons.

In a seventh embodiment, disclosed and claimed herein are compositions of matter of the above embodiments, wherein the composition is a photoresist sensitive to ultraviolet (UV), deep UV, vacuum UV, extreme UV, x-rays, electron beams and ion beams.

### EXPERIMENTAL

Below are representative examples of the zwitterions useful in the current disclosure.

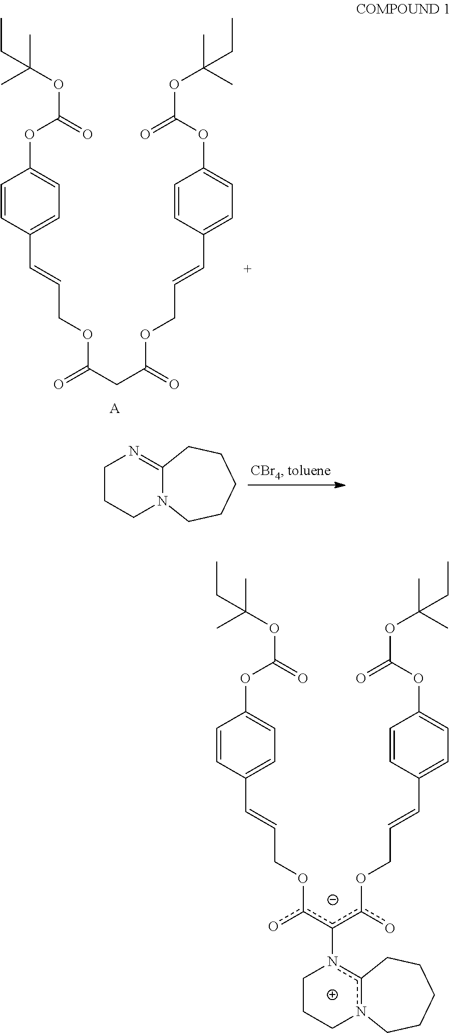

Tetrabromomethane (9.32 g, 28.10 mmol, 1.11 eq) was added to a 2 L round bottom flask. The flask was pump purged three times with inert gas and vacuum. A (15.2 g, 25.48 mmol, 1 eq) was added via a total of 1.25 L of anhydrous toluene. The mixture was stirred under nitrogen for 30 minutes until all was dissolved. 1,8-diazabicyclo[5.4.0]undec-7-ene (DBU, 16.54 ml, 110.8 mmol, 4.37 eq) was added slowly by syringe. The reaction mixture was stirred under nitrogen overnight and then filtered. The filtrate was purified via silica gel chromatography using toluene, followed by acetone, then ethyl acetate and then 1:1 ethyl acetate: isopropanol. The product was collected, and solvent was removed to give a solid (5.44 g, 29% yield). The product was evaluated by ¹H NMR.

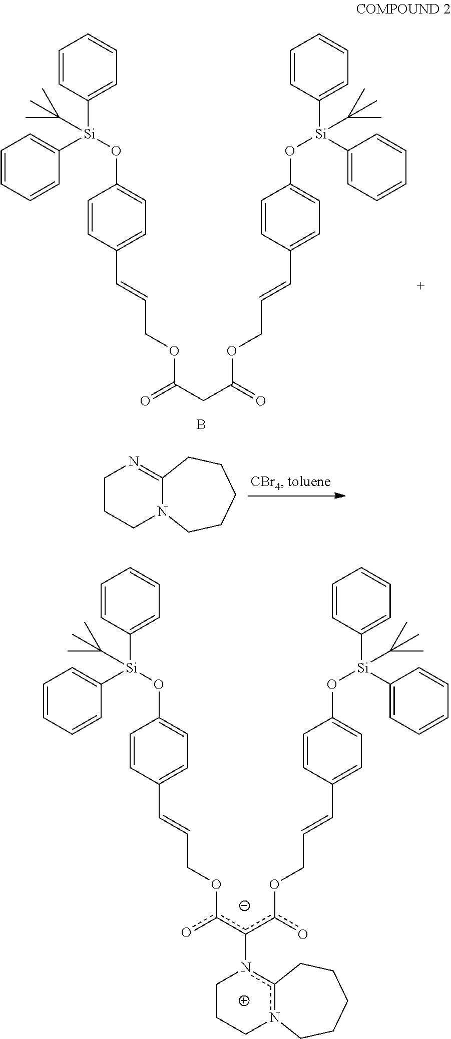

B (14.5 g, 17.16 mmol, 1 eq) was added to a 2 L round bottom flask via toluene. Tetrabromomethane (6.32 g, 19.04 mmol, 1.11 eq) was added to the same 2 L round bottom flask. Additional toluene was added up to a total of 1.21 L. The mixture was stirred under nitrogen for 30 minutes until all dissolved. The flask was pump purged three times with inert gas and vacuum. 1,8-diazabicyclo[S.4.0]undec-7-ene (DBU, 11.21 ml, 74.97 mmol, 4.37 eq) was added dropwise. The reaction mixture was stirred under nitrogen overnight and then filtered. The filtrate was purified via silica gel chromatography. The product was collected, and solvent was removed to give a solid (10.25 g, 60% yield). The product was evaluated by 1H NMR.

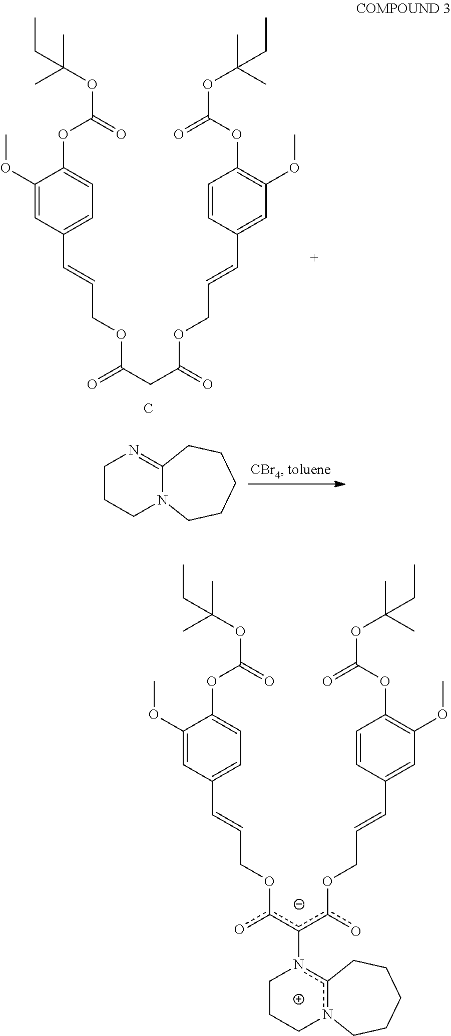

Tetrabromomethane (1.12 g, 3.38 mmol, 1.11 eq) was added to a 250 ml round bottom flask. The flask was pump purged three times with inert gas and vacuum. C (2 g, 3.05 mmol, 1 eq) was added via a total of 167 ml of anhydrous toluene. The mixture was stirred under nitrogen for 30 minutes until all was dissolved. 1,8-diazabicyclo[S.4.0]undec-7-ene (DBU, 1.99 ml, 13.31 mmol, 4.37 eq) was added dropwise over 5 minutes. The reaction mixture was stirred under nitrogen overnight and then filtered. The filtrate was purified via silica gel chromatography using toluene, followed by acetone, then ethyl acetate and then 1:1 ethyl acetate: isopropanol. The product was collected, and solvent was removed to give a solid (0.874 g, 36% yield). The product was evaluated by ¹H NMR.

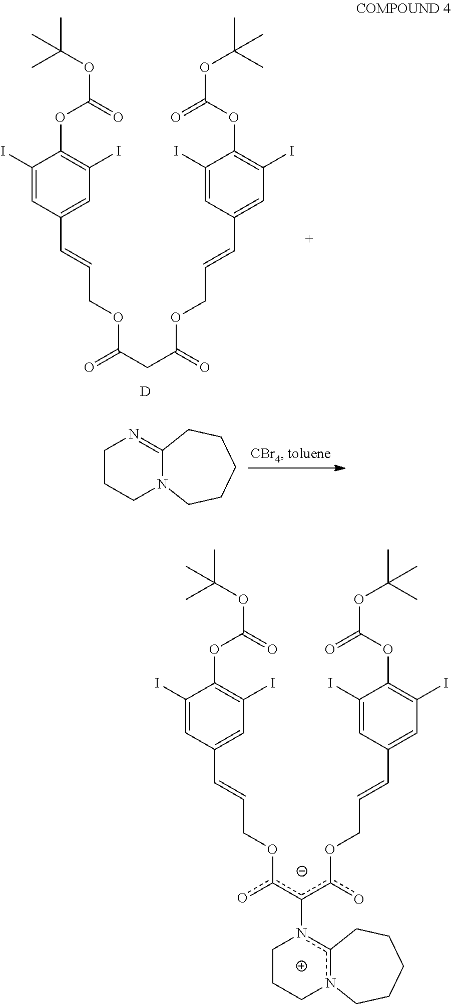

D (2 g, 1.87 mmol, 1 eq) and tetrabromomethane (0.69 g, 2.07 mmol, 1.11 eq) were added to a 500ml round bottom flask. A total of 167 ml of toluene was added to the flask. The flask was sealed, and the mixture was stirred for 30 minutes until all was dissolved. During this time, the flask was pump purged three times with inert gas and vacuum. 1,8-diazabicyclo[5.4.0]undec-7-ene (DBU, 1.22 ml, 8.15 mmol, 4.37 eq) was added dropwise while continuing to stir. The reaction mixture was stirred under nitrogen overnight and then filtered. The filtrate was purified via silica gel chromatography using toluene, followed by acetone, then ethyl acetate and then 1:1 ethyl acetate: isopropanol. The product was collected, and solvent was removed to give a solid (1.16 g, 51% yield). The product was evaluated by ¹H NMR

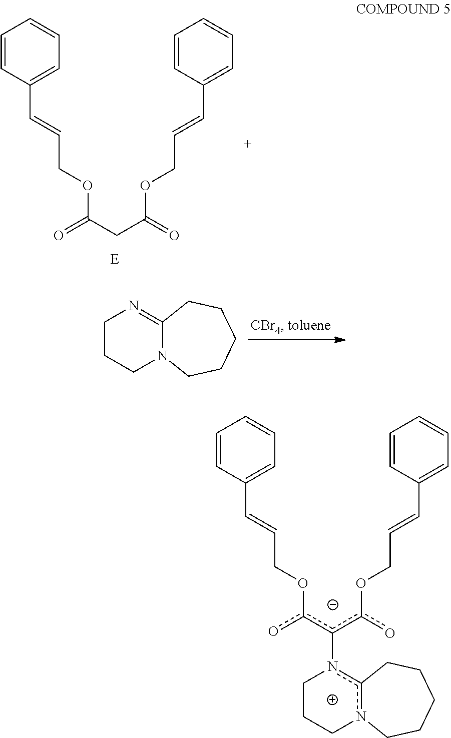

E (1.03 g, 3.06 mmol, 1 eq) and tetrabromomethane (1.13 g, 3.4 mmol, 1.11 eq) were added to a 250 ml round bottom flask. A total of 86 ml of toluene was added to the flask. The flask was sealed, and the mixture was stirred for 30 minutes until all was dissolved. During this time, the flask was pump purged three times with inert gas and vacuum. 1,8-diazabicyclo[5.4.0]undec-7-ene (DBU, 2 ml, 13.38 mmol, 4.37 eq) was added dropwise while continuing to stir. The reaction mixture was stirred under nitrogen overnight and then filtered. The filtrate was purified via silica gel chromatography using toluene, followed by acetone, then ethyl acetate and then 1:1 ethyl acetate: isopropanol. The product was collected, and solvent was removed to give a solid (0.818 g, 55% yield). The product was evaluated by ¹H NMR.

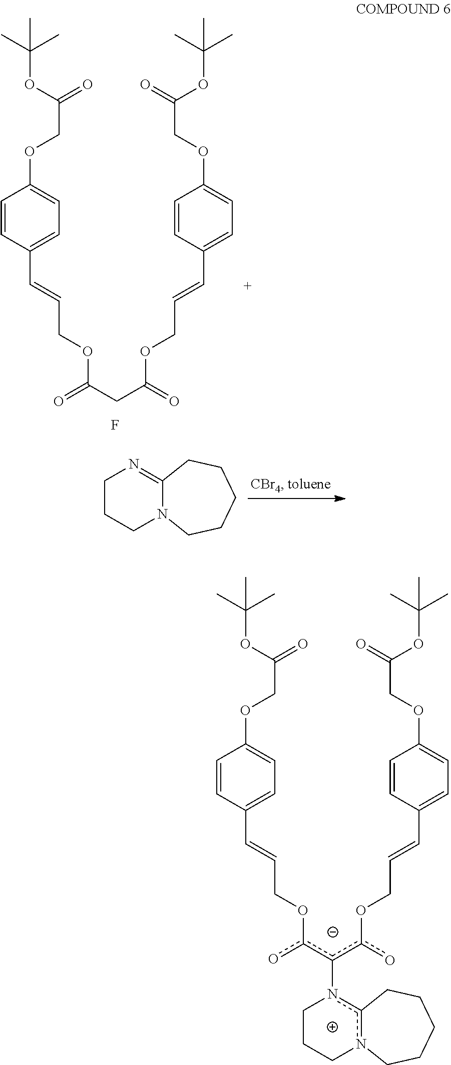

F (2.5 g, 4.19 mmol, 1 eq) and tetrabromomethane (1.54 g, 4.65 mmol, 1.11 eq) were added to a 500 ml round bottom flask. A total of 208 ml of toluene was added to the flask. The flask was sealed, and the mixture was stirred for 30 minutes until all was dissolved. During this time, the flask was pump purged three times with inert gas and vacuum. 1,8-diazabicyclo[5.4.0]undec-7-ene (DBU, 2.74 ml, 18.31 mmol, 4.37 eq) was added dropwise while continuing to stir. The reaction mixture was stirred under nitrogen overnight and then filtered. The filtrate was purified via silica gel chromatography using toluene, followed by acetone, then ethyl acetate and then 1:1 ethyl acetate: isopropanol. The product was collected, and solvent was removed to give a solid (1.23 g, 39% yield). The product was evaluated by ¹H NMR.

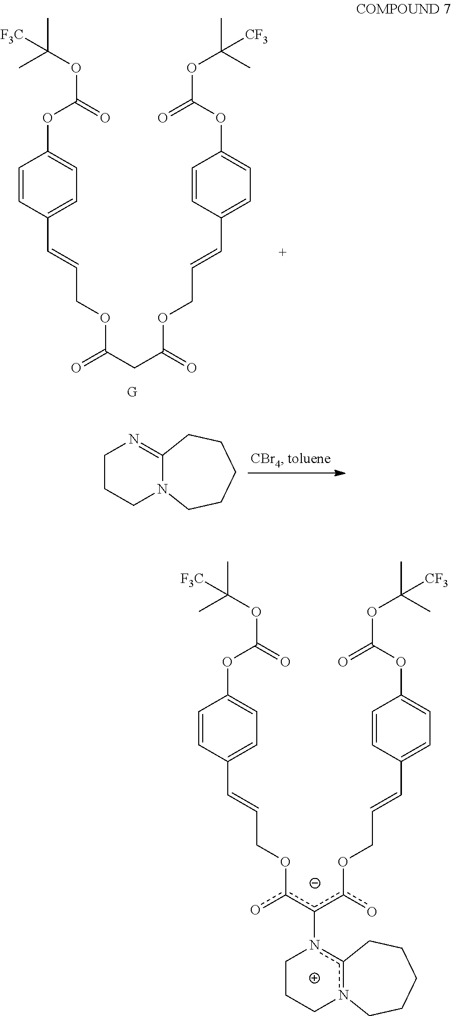

G (2.05 g, 3.03 mmol, 1 eq) and tetrabromomethane (1.12 g, 3.36 mmol, 1.11 eq) were added to a 500 ml round bottom flask. A total of 171 ml of toluene was added to the flask. The flask was sealed, and the mixture was stirred for 30 minutes until all was dissolved. During this time, the flask was pump purged three times with inert gas and vacuum. 1,8-diazabicyclo[5.4.0]undec-7-ene (DBU, 1.98 ml, 13.24 mmol, 4.37 eq) was added dropwise while continuing to stir. The reaction mixture was stirred under nitrogen overnight and then filtered. The filtrate was purified via silica gel chromatography using toluene, followed by acetone, then ethyl acetate and then 1:1 ethyl acetate: isopropanol. The product was collected, and solvent was removed to give a solid (0.558 g, 22% yield). The product was evaluated by ¹H NMR.

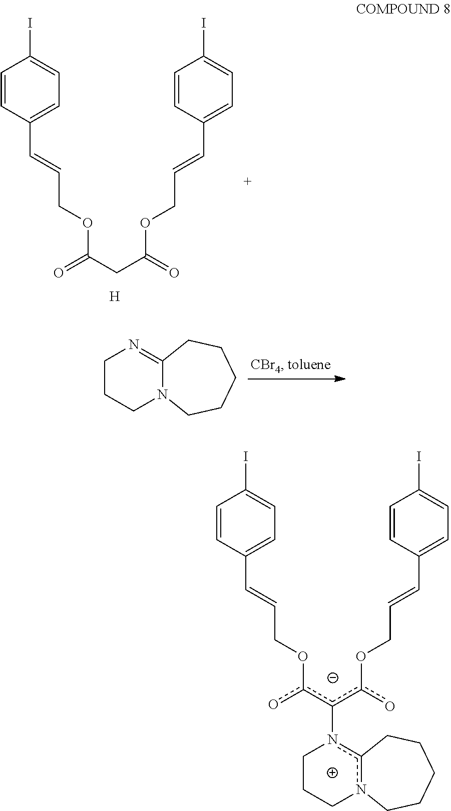

H (3.3 g, 5.61 mmol, 1 eq) and tetrabromomethane (2.07 g, 6.23 mmol, 1.11 eq) were added to a 500 ml round bottom flask. A total of 275 ml of toluene was added to the flask. The flask was sealed, and the mixture was stirred for 30 minutes until all was dissolved. During this time, the flask was pump purged three times with inert gas and vacuum. 1,8-diazabicyclo[5.4.0]undec-7-ene (DBU, 3.67 ml, 24.52 mmol, 4.37 eq) was added dropwise while continuing to stir. The reaction mixture was stirred under nitrogen overnight and then filtered. The filtrate was purified via silica gel chromatography using toluene, followed by acetone, then ethyl acetate and then 1:1 ethyl acetate: isopropanol. The product was collected, and solvent was removed to give a solid (2.00 g, 48% yield). The product was evaluated by ¹H NMR.

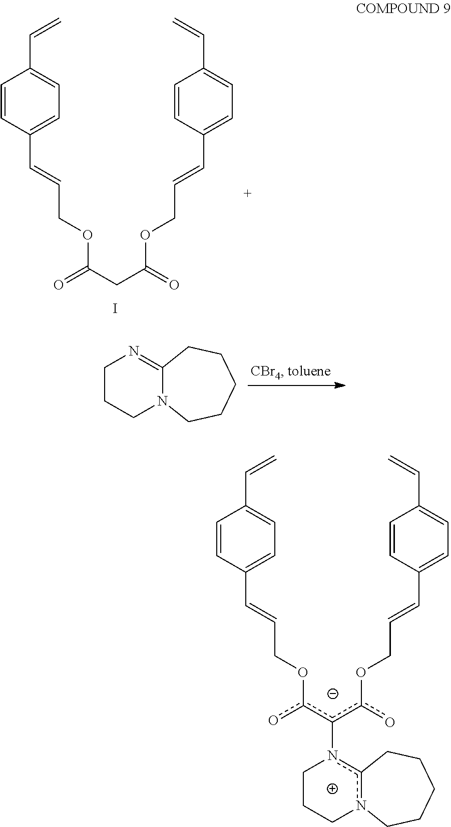

I (1.7 g, 4.38 mmol, 1 eq) and tetrabromomethane (1.61 g, 4.86 mmol, 1.11 eq) were added to a 500 ml round bottom flask. A total of 142 ml of toluene was added to the flask. The flask was sealed, and the mixture was stirred for 30 minutes until all was dissolved. During this time, the flask was pump purged three times with inert gas and vacuum. 1,8-diazabicyclo[S.4.0]undec-7-ene (DBU, 2.86 ml, 19.12 mmol, 4.37 eq) was added dropwise while continuing to stir. The reaction mixture was stirred under nitrogen overnight and then filtered. The filtrate was purified via silica gel chromatography using toluene, followed by acetone, then ethyl acetate and then 1:1 ethyl acetate: isopropanol. The product was collected, and solvent was removed to give a solid (1.48 g, 63% yield). The product was evaluated by ¹H NMR.

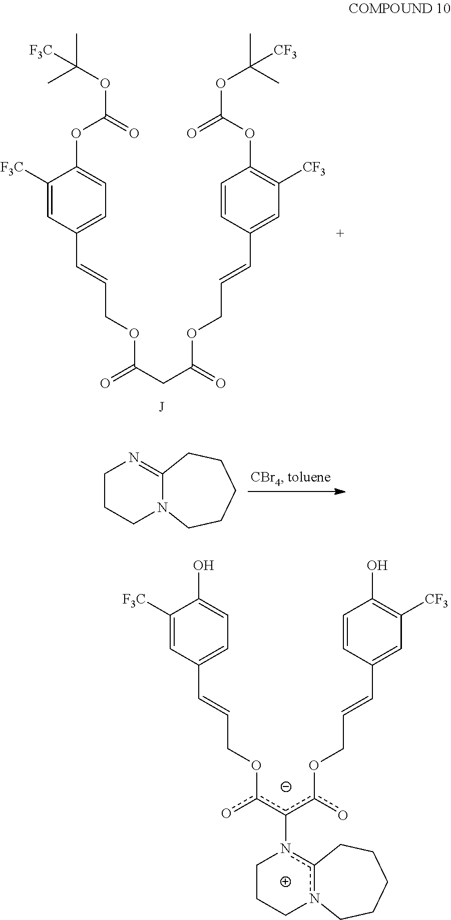

J (3.25 g, 4.00 mmol, 1 eq) and tetrabromomethane (1.47 g, 4.44 mmol, 1.11 eq) were added to a 500 ml round bottom flask. A total of 271ml of toluene was added to the flask. The flask was sealed, and the mixture was stirred for 30 minutes until all was dissolved. During this time, the flask was pump purged three times with inert gas and vacuum. 1,8-diazabicyclo[5.4.0]undec-7-ene (DBU, 2.61 ml, 17.48 mmol, 4.37 eq) was added dropwise while continuing to stir. The reaction mixture was stirred under nitrogen overnight and then filtered. The filtrate was purified via silica gel chromatography. The product was collected, and solvent was removed to give a solid (0.9 g, 34% yield). The product was evaluated by ¹H NMR.

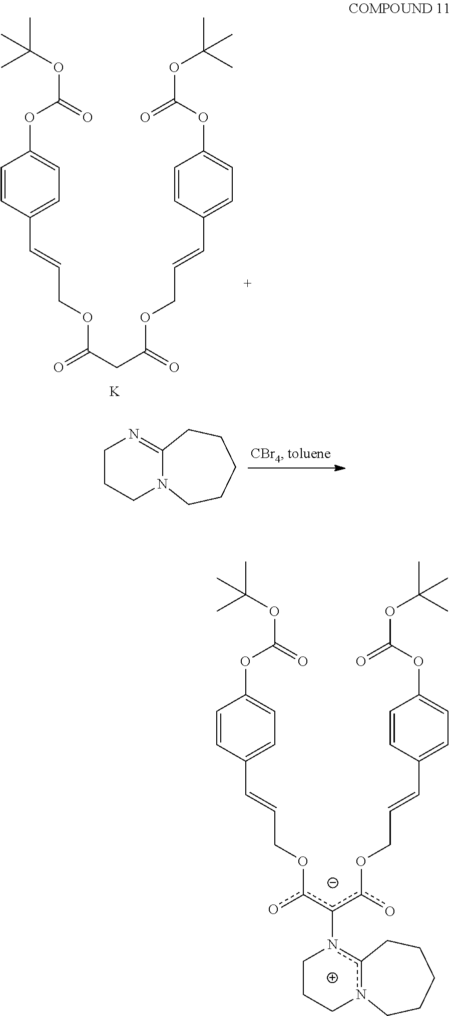

K (60 g, 105.6 mmol, 1 eq) and tetrabromomethane (38.87 g, 117.2 mmol, 1.11 eq) were added to a 12 l round bottom flask. A total of 5 l of toluene was added to the flask. The flask was sealed, and the mixture was stirred for 30 minutes until all was dissolved. During this time, the flask was pump purged three times with inert gas and vacuum. 1,8-diazabicyclo[5.4.0]undec-7-ene (DBU, 69.0 ml, 461.43 mmol, 4.37 eq) was added dropwise over 30 minutes while continuing to stir. The reaction mixture was stirred under nitrogen overnight and then filtered. The filtrate was purified via silica gel chromatography using toluene, followed by acetone, then ethyl acetate and then 1:1 ethyl acetate: isopropanol. The product was collected, and solvent was removed to give a solid (51 g, 67% yield). The product was evaluated by ¹H NMR.

### FORMULATION

General formulation: The formulation below is a general formulation in which the materials of the current disclosure were used for testing. The molar ratio were maintained when materials were tested which had different molecular weights. Techniques to remove metal content are well known in the literature.

It was also found that 2 or more zwitterion materials, including different isomers of the current disclosure could be combined in various proportions to obtain a combination to form a blend of properties of those blended zwitterions.

The percent solids in the formulation may be altered to obtain a film thickness of 20 nm when spun and dried.

536 ml of ethyl lactate, 0.495 g of {Compound 11) and 6.090 g of crosslinker (CIOI below) were admixed via sonication. The admixture was pushed through a pre-conditioned metal ion removal filter stack at 6 psi by way of a canula from the one-neck round bottom flask. To 500 ml of the admixture was added 1.595 g of PAG02, below, and 0.513 g of nucleophilic quencher Q02, below, and mixed until completely dissolved. The formulation was filtered through a 0.2 μm PTFE filter and kept protected from light and held at S° C. until use.

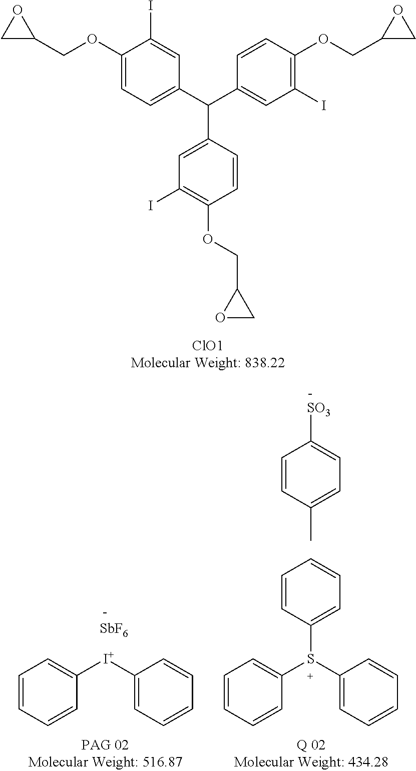

### TESTING of FORMULATIONS

Note: The formulations are prepared at such concentration to obtain a 20 nm film thickness when spun at 1500-2500 rpm and dried. The film thicknesses are measured using ellipsometry optical techniques.

A silicon wafer was spin coated at 2000 rpm using Brewer Science Optistack AL 212 underlayer and baked at 205° C. for 30 sec. The resist formulation was dispensed using a pipette onto the wafer and spun at the spin speed required to get a 20nm film thickness target, generally 1200-2300 rpm. The wafer was baked at 60 C for 3 minutes and checked that the film is still appropriate for exposure (e.g. no dewetting). The wafer was exposed using a non-contact mask using the PSI synchrotron, the mask contains patterns at pitch 44 nm line spaces and a number of die are exposed on one wafer with increasing dosages. The wafers may optionally be subjected to a post exposure bake for 1-2 minutes, generally at 60°-50° C. The wafer was immersion developed in nBA (n-butyl acetate) for 30-60 seconds and then, optionally, have a 15 second rinse in MIBC (methyl isobutyl carbinol)

The patterns were then inspected using a SEM and images were taken through dose.

The line widths and line width roughness were measured using a software package called SMILE. The line widths and LWR were plotted against dose, trendlines are calculated, and the dose required to achieve 22 nm lines is calculated from this plot; and the LWR at 22 nm lines is also recorded.

### RESULTS

FIG. 8 shows Scanning Electron Microscope images of the formulation using Compound 11 of the current disclosure.

The results show that a variety of very specific zwitterions exhibit major improvements in line width roughness or photospeed or both when used in EUV photoresists.
Critical Dimension (CD) in nanometers
Sensitivity in mJ/cm²
Line Width Roughness (LWR) in nanometers

In Chart 1 below are shown the results of the photolithographic process described herein. The Chart lists in the first column the example compounds disclosed herein. The second column shows the critical dimensions of the photoresist compositions, Column 3 shows the sensitivity to achieve the desired geometry. As can be seen

FIG. 8 shows SEMs of Compound 11 showing the increase in critical dimension with the increase in photo exposure.

Note compounds 2-7 showing very low LWR while maintaining excellent sensitivity.

| Compound | CD | LWR | Sensitivity |
|---|---|---|---|
| 2 | 17.54 | 3.17 | 34.98 |
| 4 | 19.87 | 3.70 | 46.58 |
| 8 | 20.95 | 3.19 | 51.17 |
| 9 | 20.45 | 3.04 | 55.07 |
| 10 | 19.95 | 3.09 | 56.42 |
| 12 | 21.34 | 3.59 | 50.65 |
| 14 | 22.14 | 4.19 | 44.37 |
| 15 | na | 4.65 | 39.89 |
| 21 | na | 5.25 | 65.28 |
| 23 | na | 4.15 | 39.98 |
| 24 | na | 4.17 | 48.90 |

We claim:

1. A composition of matter comprising the chemical structure: 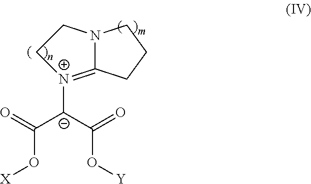
wherein m₌₌₌1-4, n₌₌₌1-4, and wherein X and Y are the same or different and are branched or unbranched, substituted or unsubstituted chains of 1-24 carbon atoms comprising alkyl groups, alkenyl groups, aromatic groups, oxygen groups, substituted aromatic groups or combinations thereof.

2. The compositions of matter of claim 1, wherein m=2 and n=3.

3. The compositions of matter of claim 1, wherein the chains have 0-16 heteroatoms substituted onto the chains and comprise substituted or unsubstituted aryl groups, heteroaromatic groups, or fused aromatic or fused heteroaromatic groups or combinations of both and wherein the aromatic groups comprise one or more substituents comprising t-butoxycarbonyloxy groups, t-butyl ester groups, t-butyl ester ether groups, t-pentoxycarbonyloxy groups, hydroxy groups, ether groups, alkyl or alkenyl substituents, alkylsilyl groups, siloxy groups comprising aromatic substituents, or a combination thereof.

4. The compositions of matter of claim 3, wherein m=2 and n=3.

5. The compositions of matter of claim 3, further comprising, in admixture, one or more photoacid generators chosen from a sulfonium salt, an iodonium salt, a sulfone imide, a halogen-containing compound, a sulfone compound, an ester sulfonate compound, a diazomethane compound, a dicarboxirnidyl sulfonic acid ester, an ylideneaminooxy sulfonic acid ester, a sulfanyldiazomethane, or a mixture thereof.

6. The compositions of matter of claim 5, frnlher comprising at least one crosslinker, wherein the at least one crosslinker comprises an acid sensitive monomer, oligomer or polymer, and wherein the at least one crosslinker comprises at least one of an epoxy group, an oxetane group, an oxabicyclo[4.1.0]heptane-ether group, a oxetanemethanol group, a glycidyl ether, a glycidyl ether of an aromatic group, glycidyl ester, glycidyl amine, a methoxymethyl group, an ethoxy methyl group, a butoxymethyl group, a benzyloxymethyl group, dimethylamino rnethyl group, diethylamino methyl group, a dibutoxymethyl group, a dimethylol amino methyl group, diethylol amino methyl group, a dibutylol amino methyl group, a rnorvholino methyl group, acetoxymethyl group, benzyloxy methyl group, formyl group, acetyl group, vinyl group or an isopropenyl group.

7. The composition of matter of claim 6 further comprising a solvent comprising ethers, esters, etheresters, ketones and ketoneesters and, more specifically, ethylene glycol monoalkyl ethers, diethylene glycol dialkyl ethers, propylene glycol rnonoalkyl ethers, propylene glycol dialkyl ethers, alkyl phenyl ethers such as anisole, acetate esters, hydroxyacetate esters, and lactate esters, such as ethyl lactate. The aforementioned solvents may be used independently or as a mixture of two or more types. Furthermore, at least one type of high boiling point solvent such as benzylethyl ether, dihexyl ether, diethylene glycol monomethyl ether, diethylene glycol monoethyl ether, acetonylacetone, isoholon, caproic acid, capric acid, 1-octanol, 1-nonanol, benzyl alcohol, benzyl acetate, ethyl benzoate, diethyl oxalate, diethyl maleate, y-butyrolactone, ethylene carbonate, propylene carbonate and phenylcellosolve acetate may be added to the aforementioned solvent. Other suitable solvents include halogenated solvents.

8. The composition of matter of claim 87 wherein the composition is a photoresist sensitive to ultraviolet (UV), deep UV, vacuum UV, extreme UV, x-rays, electron beams and ion beams.

9. A composition of matter comprising the chemical stmcture: 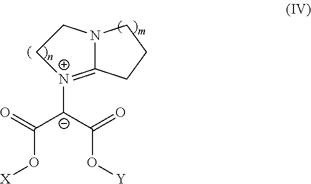
wherein m=2 and n=3. and wherein X and Y are the same or different and are branched or unbranched, substituted or unsubstituted chains of 1-24 carbon atoms comprising alkyl groups, alkenyl groups, aromatic groups, oxygen groups, substituted aromatic groups, hydroxy groups, ether groups, alkyl or alkenyl substituents, alkylsilyl groups, siloxy groups comprising aromatic substituents, or combinations thereof and wherein the chains and/or the groups on the chains are substituted with one of more iodides, fluorides, and/or fluorocarbons.

10. The cornposition of matter of claim 9, further comprising, in admixture, one or more photoacld generators chosen from a sulfonium salt, an iodonium salt, a sulfone imide, a halogen-containing compound, a sulfone compound, an ester sulfonate compound, a diazomethane compound, a dicarboximidyl sulfonic acid ester, an ylideneaminooxy sulfonic acid ester, a sulfanyldiazomethane, or a mixture thereof.

11. The compositions of matter of claim 10, further comprising at least one crosslinker, wherein the at least one crosslinker comprises an acid sensitive monomer, oligomer or polymer, and wherein the at least one crosslinker comprises at least one of an epoxy group, an oxetane group, an oxabicyclo[4.1.0]heptane-ether group, a oxetanemethanol group, a glycidyl ether, a glycidyl ether of an aromatic group, glycidyl ester, glycidyl amine, a methoxymethyl group, an ethoxy rnethyl group, a butoxymethyl group, a benzyloxymethyl group, dirnethylamino methyl group, diethylamino methyl group, a dibutoxymethyl group, a dimethylol arnino methyl group, diethylol amino rnethyl group, a dihutylol amino methyl group, a morphollno methyl group, acetoxymethyl group, benzyloxy methyl group, formyl group, acetyl group, vinyl group or an isopropenyl group.

12. The compositions of claim 11, wherein the crosslinkers comprise aromatic substituents which are substituted with iodide groups, fluoride groups, alkyl-fluoride groups or a combination thereof.

13. The composition of matter of claim 12, further comprising a solvent comprising ethers, esters, etheresters, ketones and ketoneesters and, more specifically, ethylene glycol monoalkyl ethers, diethylene glycol dialkyl ethers, propylene glycol monoalkyl ethers, propylene glycol dialkyl ethers, alkyl phenyl ethers such as anisole, acetate esters, hydroxyacetate esters, and lactate esters, such as ethyl lactate. The aforementioned solvents may be used independently or as a mixture of two or more types. Furthermore, at least one type of high boiling point solvent such as benzylethyl ether, dihexyl ether, diethylene glycol monomethyl ether, diethylene glycol monoethyl ether, acetonylacetone isoholon, caproic acid, capric acid, 1-octanol, 1-nonanol, benzyl alcohol, benzyl acetate, ethyl benzoate, diethyl oxalate, diethyl maleate, y-butyrolactone, ethylene carbonate, propylene carbonate and phenylcellosolve acetate may be added to the aforementioned solvent. Other suitable solvents include halogenated solvents.

14. The composition of matter of claim 13 wherein the composition is a photoresist sensitive to ultraviolet (UV), deep UV, vacuum UV, extreme UV, x-rays, electron beams and ion beams.
